(19) United States
(12) Patent Application Publication
(10) Pub. No.: US 2024/0303394 A1
(43) Pub. Date: Sep. 12, 2024

(54) OPTIMIZATION METHOD FOR OUTLIER DATA IDENTIFICATION IN TRAFFIC EMISSION QUOTA ALLOCATION PROCESS

(71) Applicants: SUN YAT-SEN UNIVERSITY, Guangzhou (CN); GUANGDONG UNIVERSITY OF TECHNOLOGY, Guangzhou (CN)

(72) Inventors: Yonghong LIU, Guangzhou (CN); Weichi LI, Guangzhou (CN); Xuelan ZENG, Guangzhou (CN); Zhi YU, Guangzhou (CN); Qingman HE, Guangzhou (CN); Jiajun HE, Guangzhou (CN)

(73) Assignees: SUN YAT-SEN UNIVERSITY, Guangzhou (CN); GUANGDONG UNIVERSITY OF TECHNOLOGY, Guangzhou (CN)

(21) Appl. No.: 18/658,376

(22) Filed: May 8, 2024

Related U.S. Application Data
(63) Continuation of application No. PCT/CN2023/082597, filed on Mar. 20, 2023.

(30) Foreign Application Priority Data
Jun. 7, 2022 (CN) 202210636946.1

(51) Int. Cl. G06F 30/20

(52) U.S. Cl. CPC G06F 30/20

(57) ABSTRACT

The present disclosure relates to an optimization method of outlier data identification in a traffic emission quota allocation process. This method includes: constructing a traffic emission quota allocation model; calculating a unit output-input value for each input of each vehicle in a reference set D; identifying outlier vehicles by using a combination of isolation forest model-generalized super efficiency model; and removing final outlier vehicles from the reference set D to obtain a reference set D″ with the final outlier vehicles being removed.

### CROSS-REFERENCE TO RELATED APPLICATIONS

This patent application is a bypass continuation application of International Application No. PCT/CN2023/082597 (filed 20 Mar. 2023), which claims priority to Chinese Patent Application No. 202210636946.1 (filed 7 Jun. 2022), the contents of which are incorporated herein by reference in their entireties.

### TECHNICAL FIELD

The present disclosure relates to the technology field of environment management, and in particular to an optimization method of outlier data identification in a traffic emission quota allocation process.

### BACKGROUND

The pollution and climate change problem resulting from traffic is a big problem for urban management. Along with the intensifying control of countries on pollutants and carbon emissions, the traffic, as one of the major sources of urban pollution and carbon emission, will play an important role in emission reduction. The market mechanism for the pollution and carbon emission control is an effective policy tool to achieve an emission control target at a low cost. Across the world, there are many countries and regions which have already established emission trading market, for example, the SO₂ and NOₓ emission trading markets established by USA. Several cities in China have carried out a pilot SO₂ emission trading market, and there are 25 countries which have carried out a CO₂ trading market. In essence, the emission trading is that the government formulates a total volume upper limit of the pollutant or carbon emission right, and then issues emission quotas. The quota allocation is extremely critical for the operation of the emission trading mechanism, because the emission quotas are highly related to the benefits of the controlled entities, for example, relate to policy guidance, incentive effect and political acceptability.

### SUMMARY

In order to address the defects in the related arts, the present disclosure provides an optimization method of outlier data identification in a traffic emission quota allocation process, in which outliers can be identified relatively quickly and accurately in an automatic way in a quota allocation process.

In order to achieve the above purpose, the following technical solution of the present disclosure is provided.

There is provided an optimization method of outlier data identification in a traffic emission quota allocation process, which includes the following steps:
at step S1, constructing a traffic emission quota allocation model;
at step S2, calculating a unit output-input value for each input of each vehicle in a reference set D;
at step S3, identifying outlier vehicles in the reference D by using a combination of isolation forest-generalized super efficiency model;
at step S4, removing final outlier vehicles from the reference set D to obtain a reference set D″ with the final outlier vehicles being removed;
at step S5, calculating a quota amount of a to-be-allocated vehicle based on the reference set D″; and
at step S6, dynamically updating the reference set D″, and dynamically identifying the outlier vehicles.

Furthermore, in the above optimization method of the outlier data identification in the traffic emission quota allocation process, the step S1 includes:
at step S1-1, setting a quota allocation object;
at step S1-2, setting an input index and an output index of the quota allocation model; where the input index includes a pollutant emission amount, a carbon dioxide emission amount and travel time of the to-be-allocated vehicle during a travel process, and the output index includes a travel distance of the to-be-allocated vehicle during the travel process.
at step S1-3, setting a reference set D for forming an efficiency frontier, where the reference set D is selected from a set of travel processes (may be referred as sample units) of vehicles within a certain time and space range of quota management;
at step S1-4, setting a distance function of the quota allocation model, where the distance function includes a radial distance function, a function of farthest distance to frontier, a function of shortest distance to weak or strong effective frontier, and a directional distance function;
at step S1-5, setting a returns-to-scale type, where the returns-to-scale type includes returns-to-scale being constant and returns-to-scale being variable; and
at step S1-6, determining the quota allocation model.

Furthermore, in the above optimization method of the outlier data identification in the traffic emission quota allocation process, the quota allocation object (which may also refer as to-be-allocated vehicle or to-be-allocated unit) set in the step S1-1 represents a travel process of a vehicle for a time length within the certain time and space range of the quota management. The identity of the individual vehicle (e.g., the number plate of the vehicle included in the quota allocation) and the time length can be set by the manager.

Furthermore, in the above optimization method of the outlier data identification in the traffic emission quota allocation process, the input index of the quota allocation model set in the step S1-2 includes a pollutant emission amount, a carbon dioxide emission amount and a travel time of the to-be-allocated vehicle.

Furthermore, the pollutant emission amount and the carbon dioxide emission amount of the vehicle are calculated by vehicle exhaust on-line monitoring equipment or by vehicle emission model, and the travel time and travel distance of the to-be-allocated vehicle can be obtained from vehicle travel monitoring database.

Furthermore, in the above optimization method of the outlier data identification in the traffic emission quota allocation process, the output index of the quota allocation model set in the step S1-2 includes a travel distance of the to-be-allocated vehicle, which can be obtained from GPS data and license plate recognition data of the to-be-allocated vehicle in the vehicle travel monitoring database.

Further, for the optimization method of outlier data identification in the process of traffic emission quota allocation mentioned above, in S1-3, selecting from a set of travel processes of vehicles (may be referred as sample units) within a certain time and space range of quota management, the time and space range can be set by the manager, such as the whole year in the quota management area. The time length and partition mode of the sample unit (travel process of the vehicle) is consistent with that of a to-be-allocated unit (travel process of a to-be-allocated vehicle).

Furthermore, in the above optimization method of the outlier data identification in the traffic emission quota allocation process, the distance function in the step S1-4 is a radial distance function.

Furthermore, in the above optimization method of the outlier data identification in the traffic emission quota allocation process, when setting the returns-to-scale type in the step S1-5, if a range with time as day or month scale is selected, the returns-to-scale is constant; if a range with time as year scale is selected, the returns-to-scale is variable.

Furthermore, in the above optimization method of the outlier data identification in the traffic emission quota allocation process, when determining the quota allocation model in the step S1-6,

if the returns-to-scale is constant, there is a following model for a to-be-allocated vehicle p to be allocated a quota:

$$min θ , \qquad ( Formula 4 )$$

$$s . t . {\sum }_{m} {\overline{x}}_{m} {λ}_{m} \leq θ {x}_{p} ,$$

$${\sum }_{m} {\overline{y}}_{m} {λ}_{m} \geq {y}_{p} ,$$

$${λ}_{m} \geq 0 ,$$

$$m ∈ {D}^{″} .$$

in the above model, the optimal solution θ represents an efficiency score of the to-be-allocated vehicle p to be allocated a quota, λₘ represents a linear combination coefficient of an efficiency frontier vehicle in the reference set, θxₚ represents to a quota amount obtained by the to-be-allocated vehicle p, xₚ and yₚ represent to an input index value and an output index value of the to-be-allocated vehicle p to be allocated a quota, x̅ₘ and y̅ₘ represent to an input index value and an output index value of the vehicle m in the reference set; the input index includes a pollutant emission amount, carbon dioxide emission amount and a travel time; the output index includes a travel distance;

if the returns-to-scale is variable, a constraint condition Σₘλₘ=1 is added to the formula (4) and other settings are unchanged.

In order to control the total amount of regional emissions, it is necessary to set an upper limit of the regional cumulative allocation quota in the corresponding control period. The total amount of regional emissions can be set according to the total amount of historical emissions of regional vehicles, the total amount of predicted emissions, the regional environmental capacity and the emission reduction policy. Within the time range corresponding to the regional cumulative quota upper limit, the cumulative amount of any gas quota allocated to the to-be-allocated vehicles should not exceed the quota upper limit of the corresponding gas.

Furthermore, in the above optimization method of the outlier data identification in the traffic emission quota allocation process, the step S2 includes:

for each input of a vehicle, calculating a unit output-input value for each input as follows:

$${E}_{h , k , m} = \frac{{Input}_{h , m}}{{Output}_{k , m}} \qquad ( Formula 5 )$$

where E_{h,k,m} represents a ratio of a value of h-th input to a value of the k-th output of the vehicle m, Input_{h,m} represents the value of the h-th input and Output_{k,m} represents the value of the k-th output. In the application, the input index of the vehicle includes respective pollutants emission amount, a greenhouse gas emission amount and a travel time of a vehicle during a travel process; the output index includes a travel distance of the vehicle during the travel process.

Furthermore, the pollutant emission amount and the greenhouse gas emission amount of each input of the vehicle are calculated by vehicle exhaust on-line monitoring equipment or by vehicle emission model, and the travel time and travel distance of the vehicle can be obtained from vehicle travel monitoring database

Furthermore, in the above optimization method of the outlier data identification in the traffic emission quota allocation process, the step S3 includes:
at step S3-1, pre-identifying potential outlier vehicles in the reference set D by running the isolation forest model; where, each vehicle is equivalent to one point in a h*k-dimensional space, and identifying the potential outlier vehicles in a multi-dimensional space based on isolation forest algorithm;
setting parameters of the isolation forest model to default values, iTree number T=100 and sub-sampling size=256;
for each vehicle, obtaining a corresponding anomaly score, which represents an outlier degree of the vehicle, where those vehicles with the anomaly score greater than 0.6 are considered as the potential outlier vehicles;
at step S3-2, removing the potential outlier vehicles from the reference set D to obtain a reference set D′;
at step S3-3, identifying, based on a generalized super efficiency DEA model, the final outlier vehicles in the reference set D, and with the vehicles in the reference set D′ as the reference set of the generalized super efficiency DEA model, evaluating a super efficiency score of the vehicles in the reference set D;
where, when the returns-to-scale is constant, programming formulations of the generalized super efficiency DEA model are as follows:

$$min φ , \qquad ( Formula 6 )$$

$$s . t . {\sum }_{r} {\overline{x}}_{r} {λ}_{r} \leq φ {\overline{x}}_{t} ,$$

$${\sum }_{r} {\overline{y}}_{r} {λ}_{r} \geq {\overline{y}}_{t} ,$$

$${λ}_{r} \geq 0 ,$$

$$r ∈ {D}^{′} ,$$

$$t ∈ D .$$

In the above model, φ represents a super efficiency score, λᵣ is a linear combination coefficient of a efficiency frontier vehicle, x̅ᵣ and y̅ᵣ represent an input index value and an output index value of the vehicle r in the reference set D′, X̅ₜ and y̅ₜ represent an input index value and an output index value of the vehicle t in the reference set D, where the input index includes a pollutant emission amount, a carbon dioxide emission amount, and a travel time of the vehicle, and the output index includes a travel distance of the vehicle;
when the returns-to-scale is variable, a constraint condition Σᵣλᵣ=1 is added to the formula (6), and other settings are unchanged;
vehicles with the super efficiency score greater than 1 are determined as final outlier vehicles.

In some embodiments, the step S5 of calculating the quota of the vehicle based on the reference set D″ includes:
for the to-be-allocated vehicle p to be allocated a quota, obtaining quota amounts θx₁ₚ, θx₂ₚ, . . . . θxₕₚ for the to-be-allocated vehicle p by running Formula 4 with the reference set D″ as the reference set, where θx₍ₕ₋₁₎ₚ, represents quota amount of each pollutant (input) for the to-be-allocated vehicle p.

In some embodiments, the step S6 of dynamically updating the reference set D″, and dynamically identifying outlier vehicles includes:
adding emission data and travel data of vehicles appearing in a period to the reference set D″ to obtain a reference set D′″, identifying outlier vehicles in the reference set D′″ continuously, and removing the identified outlier vehicles to obtain an updated reference set D″″, that is, in the management area, the quota allocation mechanism can update the reference set every certain time to adapt to the latest situation of traveling and emission of the vehicle.

Compared with the related arts, the optimization method of the outlier data identification in the traffic emission quota allocation process has the following advantages and beneficial effects.
1. The optimization method of the outlier data identification in the traffic emission quota allocation process in the present disclosure can detect outliers efficiently and identify the outliers relatively quickly and accurately in an automatic way in the quota allocation process.
2. The optimization method of the outlier data identification in the traffic emission quota allocation process in the present disclosure is superior to the conventional super efficiency model method and can reduce the error largely.
3. The optimization method of the outlier data identification in the traffic emission quota allocation process in the present disclosure features high accuracy and high automation degree and requires fewer human interventions.

### BRIEF DESCRIPTION OF DRAWINGS

FIG. 1 is a flowchart illustrating an optimization method of outlier data identification in a traffic emission quota allocation process in the present disclosure.

FIG. 2 is a flowchart of a traffic emission quota allocation model in the present disclosure.

FIG. 3 is a flowchart of identifying outlier vehicles in a quota allocation reference set in the present disclosure.

FIG. 4 is a schematic diagram illustrating a simulation data distribution of outlier data identification in a traffic emission quota allocation process in the present disclosure.

### DETAILED DESCRIPTION

In order to more clearly understand the above objects, features and advantages of the present disclosure, the present disclosure will be further detailed below in combination with drawings and specific embodiments. It should be noted that in case of no conflicts, the embodiments and the features of the embodiments of the present disclosure can be mutually combined.

Many details are set forth in the following descriptions to help fully understand the present disclosure. However, the present disclosure may also be practiced by other embodiments different from those described herein, and therefore, the scope of protection of the present disclosure is not limited to the specific embodiments disclosed hereunder.

In the present specification, the illustrative expressions of these terms are not necessarily directed to same embodiments or examples. Further, the specific features, steps, methods or features described herein may be combined properly in one or more embodiments or examples.

Data Envelopment Analysis (DEA), as a cross research field of operational research and mathematical economics, is a typical data-driven nonparametric benchmark technology which has been widely applied in quota allocation research. This method is a nonparametric analysis method in which, based on multiple input indexes and multiple output indexes, a linear planning method is used to perform relative efficiency evaluation on comparable evaluated objects of same type. These evaluated objects are referred to as Decision Making Units (DMU). Each DMU uses h inputs to generate k outputs. In these DMUs, the DMUs which can obtain a maximum output with the existing input or maintain the existing output with a minimum consumption are referred to as efficient DMUs. A curve (surface) formed by the efficient DMUs is referred to as efficiency frontier. As a nonparametric performance evaluation method, the DEA does not need to make pre-estimation or assumption on a weight of the integrated input and output and a form of the efficiency frontier, so as to avoid the influence of various objective factors. However, the DEA is very sensitive to the extreme values or outliers, because it is possible for the DEA to estimate the efficiency frontier based on extreme DMUs, which usually leads to severe error in the estimation of the efficiency score of other DMUs. As a result, investigation should be firstly carried out to determine whether the data used contains outliers, and then, the outliers are removed to increase the accuracy of the efficiency frontier estimation. Since the outliers may be divided into efficient outliers and inefficient outliers, and the efficient outliers affect the efficiency frontier, the outliers mentioned hereinafter refer to efficient outliers.

The DEA model has been widely applied to the research of the emission quota allocation. In the background of the emission quota allocation, the DMUs can be regarded as individuals to be allocated quotas, and the quotas that the DMUs should obtain can be used as input or output in the efficiency indexes. If the outliers are involved in formation of the efficiency frontier, an error may be easily generated for the efficiency evaluation, such that there is an improper quota gap with the objects to which the quotas are allocated, which severely affects the normal operation of the emission trading market. Therefore, it is required to remove the outliers in the formation process of the efficiency frontier, so as to avoid excessive negative impact on the quota allocation.

The outlier identification of the DEA model may include a DEA-model-independent outlier identification and a DEA-model-based outlier identification. There are several DEA-model-based outlier identifications as follows. The identification method based on the concept of super efficiency is to first form an efficiency frontier after removing one or some DMUs, and then evaluate the super efficiency score of DMUs based on this efficiency frontier. DMUs that are greater than the preset threshold are considered as outlier values, the typical super efficiency method randomly removes a percentage of DMU. Although this method is easy to operate, such results may not be possible to identify outlier values. In addition, the accuracy of identifying outlier values using the super efficiency method and the impact of incorrect identification are not yet clear. The order-m method is another method based on the concept of super efficiency, which selects m DMUs from the overall DMU dataset and estimates their efficiency frontier, and then evaluates the super efficiency scores of all DMUs. Compared with the typical super efficiency method, the number of DMUs constructing the frontier is less than the overall DMU, which to some extent reduces the “masking” effect. However, the selection of parameters such as m in this method requires a lot of manual inspection, and the discrimination effect is more sensitive to the selection of parameters such as m. In terms of other methods, the methods proposed by Khezrimotlagh et al. can also reduce the “masking” effect, but it is required to operate the standard DEA model multiple times and thus a large amount of computational resource and time will be consumed in processing a large dataset.

For the DEA-model-independent outlier identification, there are some classical statistics methods, that is, outliers are identified in advance in a dataset by using distributional hypothesis. Bogetoft and Otto proposed a method of data cloud. However, this method has a shortcoming that no consideration is given to the position of the DMUs in the multi-dimensional space, which means that it is necessary to separately perform the method on all possible DMU combinations once. Smirlis and Despotis use box plots to identify the extreme values in each input and output of the DMUs and perform correction based on integration of piecewise concave function. However, the problem of this method is that, the identified outlier values were not excluded from the dataset, and some correct extreme values may have been incorrectly modified. The methods mentioned above have their respective inevitable defects. The defect of the DEA-model-based method is that the identification process of the outliers is affected by the outliers themselves or a large number of human determinations are required or a large number of computational resources are to be consumed; the DEA-independent outlier identification method is too general to consider the particularity of the DEA analysis.

Along with prosperous development of sciences and technologies, the big data era is coming. Due to the large number and frequent movements of vehicles, a large volume of spatiotemporal big data about travels and emissions of the vehicles will be used in the process of quota allocation (Especially the formation and updating of efficiency frontiers). For the related DEA outlier identification method, there are difficulties in the efficient processing of the big data to some degree. Some methods have limited effect in outlier identification, or have low efficiency of calculation, or are non-automatic methods, or require a large number of human interventions. As a result, we propose a combination method, which is a DEA-model-oriented outlier identification optimization method based on isolation forest method and super efficiency model, which can perform outlier identification relatively quickly and accurately in an automatic way in a quota allocation process.

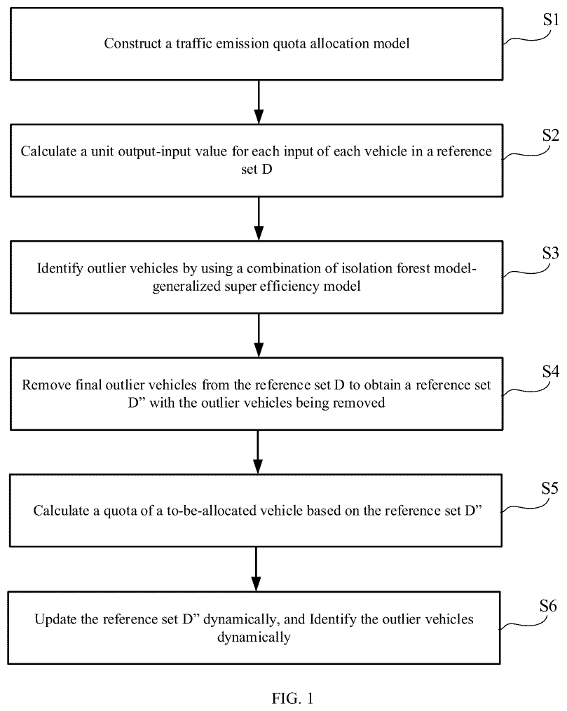

The technical solutions of the present disclosure will be further described below in combination with FIG. 1 to FIG. 4 and embodiments.

### Embodiment 1

As shown in FIG. 1, the present embodiment provides an optimization method of outlier data identification in a traffic emission quota allocation process, which includes steps S1 to S6.

At step S1, a traffic emission quota allocation model is constructed.

At step S2, a unit output-input value for each input of each vehicle in a reference set D is calculated.

At step S3, outlier vehicles in the reference set D are identified by using a combination of isolation forest model-generalized super efficiency model.

At step S4, final outlier vehicles are removed from the reference set D to obtain a reference set D″ with the outlier vehicles being removed.

At step S5, a quota of to-be-allocated vehicle is calculated based on the reference set D″.

At step S6, the reference set D″ is dynamically updated, and outlier vehicles is dynamically identified.

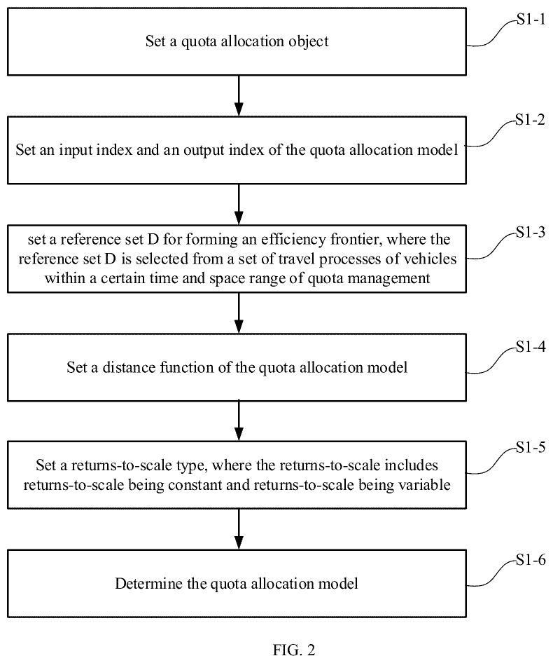

As shown in FIG. 2, the step S1 of constructing the traffic emission quota allocation model includes step S1-1 to step S1-6.

At step S1-1, a quota allocation object is set: in the present disclosure, the quota allocation object (which may also be referred as to-be-allocated vehicle or to-be-allocated unit) represents a travel process of a vehicle for a time length (for example, 5 min) within the certain time and space range of the quota management. The identity of the individual vehicle and the time length can be set by the manager. The individual vehicle forms a to-be-allocated unit when the individual vehicle appears in the spatio-temporal scope of quota management and the time length of the individual vehicle accumulates to a preset time length. Similarly, the next to-be-allocated unit is formed when the individual vehicle appears in the spatio-temporal scope of quota management and the subsequent travel time of the individual vehicle accumulates to the preset time length, and so on.

At step S1-2, an input index and an output index of a quota allocation model are set, the quota allocation model is constructed based on a basic framework of a generalized DEA method. The quota allocated to the to-be-allocated vehicle is determined based on the efficiency score of the to-be-allocated vehicle, the cumulative amount of any gas quota allocated to the to-be-allocated vehicle should not exceed the quota upper limit of the corresponding gas. The efficiency score of the to-be-allocated vehicle is calculated based on the input index and output index by using the quota allocation model constructed based on the generalized DEA. The input index includes an emission amount of various pollutants, a greenhouse gas emission amount, and a travel time, and the output index includes a travel distance.

Furthermore, the pollutant emission amount and the carbon dioxide emission amount of the to-be-allocated vehicle are calculated by vehicle exhaust on-line monitoring equipment or by vehicle emission model (for example, MOVES model and IVE model). The vehicle emission model usually needs the vehicle type, travel time, travel distance and other parameters of the to-be-allocated vehicle, which can be obtained from the vehicle travel monitoring data such as GPS data and license plate recognition data of the to-be-allocated vehicle and the vehicle registration database.

At step S1-3, a reference set for forming an efficiency frontier is set, and the efficiency frontier is an evaluation standard used to evaluate an efficiency score of the to-be-allocated vehicle, the efficiency score is configured to calculate the quota of the to-be-allocated vehicle. In the present disclosure, the formation of the efficiency frontier is based on a reference set, the reference set is determined by a set of travel processes of vehicles (may be referred as sample units) within a certain time and space range of quota management, the manager can determine a set of travel processes of travel vehicles appeared in the quota management area for a long historical period, so as to fully reflect vehicle travels and emission features in a long period within a region. The time length and allocated mode of the sample unit should be consistent with that of the to-be-allocated vehicle (to-be-allocated unit). The initial reference set, which is not processed for outlier vehicle removal, is the reference set D.

At step S1-4, a distance function of the quota allocation model is set, the distance function and the efficiency frontier jointly determine a quota amount allocated to a to-be-allocated vehicle. The distance function can be selected from: a radial distance function, a function of farthest distance to frontier, a function of shortest distance to weak or strong effective frontier, and a directional distance function and the like. In the present disclosure, the distance function is set to a radial distance function commonly used in the relevant literatures.

At step S1-5, a returns-to-scale type is set. For vehicle emissions, the returns-to-scale can be reflected in that, along with the increasing travel distance of a vehicle, the emission intensity of a vehicle may change along with change of the travel distance due to the reasons such as degradation effect and the like. Within a range with time as day or month scale, it is can be considered that there is no degradation effect, and the returns-to-scale being constant can be assumed; within a range with time as year scale, it can be considered that there is degradation effect and the returns-to-scale being variable can be assumed.

At step S1-6, the quota allocation model is determined.

If there are U to-be-allocated vehicles to be allocated quotas and S vehicles in the reference set, h input indexes (i=1,2,3 . . . h) and k output indexes are represented as follows: xₚ=(x₁ₚ, x₂ₚ, . . . , xₕₚ)^{T} represents an input index value of the to-be-allocated vehicle p to be allocated a quota, yₚ=(y₁ₚ, y₂ₚ, . . . , yₖₚ)^{T} represents an output index value of the to-be-allocated vehicle p to be allocated a quota, X̅ₘ and y̅ₘ represent an input index value and an output index value of the vehicle m in the reference set. The input index includes respective pollutant emission amounts (i=1, 2, 3, . . . h-1) and a travel time (i=h) of a to-be-allocated vehicle and the output index includes a travel distance of the to-be-allocated vehicle. ω=(ω₁, ω₂, . . . , ωₕ)^{T} represents a weight of the input index, and μ=(μ₁, μ₂, . . . , μₖ)^{T} represents a weight of the output index.

The emission efficiency of the to-be-allocated vehicle p to be allocated a quota is represented as

$$\frac{{μ}^{T} {y}_{p}}{{ω}^{T} {x}_{p}} ,$$

and a proper weight coefficient is selected by the programming formulations to maximize the emission efficiency of the to-be-allocated vehicle p. When the returns-to-scale is constant, the to-be-allocated vehicle p to be allocated a quota has the following model:

$$max \frac{{μ}^{T} {y}_{p}}{{ω}^{T} {x}_{p}} , \qquad ( Formula 7 )$$

$$s . t . \frac{{μ}^{T} {\overline{y}}_{m}}{{ω}^{T} {\overline{x}}_{m}} \leq 1 , m ∈ {D}^{″}$$

$$ω \geq 0 ,$$

$$μ \geq 0.$$

Dual transformation is performed on the formula (7) and then the formula (7) can be expressed as follows:

$$min θ , \qquad ( Formula 8 )$$

$$s . t . {\sum }_{m} {\overline{x}}_{m} {λ}_{m} \leq θ {x}_{p} ,$$

$${\sum }_{m} {\overline{y}}_{m} {λ}_{m} \geq {y}_{p} ,$$

$${λ}_{m} \geq 0 ,$$

$$m ∈ {D}^{″} .$$

In the above model, the optimal solution θ represents an efficiency score of the to-be-allocated vehicle p to be allocated a quota, λₘ represents a linear combination coefficient of an efficiency frontier vehicle, which is equivalent to comparing the to-be-allocated vehicle p to be allocated a quota with an efficient vehicle with an input being x=Σₘ X̅ₘλₘ, and an output being y=Σₘy̅ₘλₘ on the efficiency frontier. Compared with the efficient frontier, the smaller θ is, the larger input that can be reduced is and the more backward emission efficiency is. In this research, with Σₘ X̅ₘλₘ on the efficiency frontier, i.e., θ xₚ as a quota amount, the effect that the more backward the emission efficiency is, the smaller the quota amount is, can be achieved and thus the effect of penalizing the backward and encouraging the advanced can be achieved. When the returns-to-scale is variable, a constraint condition Σₘλₘ=1 can be added to the formula (8) and other settings are unchanged.

In order to control the total amount of regional emissions, it is necessary to set an upper limit of the regional cumulative allocation quota in the corresponding control period. The total amount of regional emissions can be set according to the total amount of historical emissions of regional vehicles, the total amount of predicted emissions, the regional environmental capacity and the emission reduction policy. Within the time range corresponding to the regional cumulative quota upper limit, the cumulative amount of any gas quota allocated to the to-be-allocated vehicles should not exceed the quota upper limit of the corresponding gas. The quota amount θxₚ of to-be-allocated vehicle p is calculated by Formula 8, if a sum of pollutant quotas of to-be-allocated vehicles 1, 2 . . . p-1, p exceeds a total amount of the pollutant quota, for the pollutant, only the remaining part of the total amount of the pollutant quota will be allocated to to-be-allocated vehicle p after a part of the total amount of pollutant quota is allocated to the to-be-allocated vehicle p-1, and the amount of the pollutant quota in the subsequent to-be-allocated vehicles during the quota management period will be 0.

At step S2, the unit output-input value for each input of each vehicle in the reference set is calculated. For each input item of the vehicle, a unit output-input value for each input item is calculated as follows:

$${E}_{h , k , m} = \frac{{Input}_{h , m}}{{Output}_{k , m}} \qquad ( Formula 9 )$$

where E_{h,k,m} represents a ratio of a value of the h-th input to a value of the k-th output of the vehicle m, Input_{h,m} represents the value of the h-th input and Output_{k,m} represents the value of the k-th output. In the application, the input index of the vehicle includes a pollutant emission amount, a greenhouse gas emission amount and a travel time of a vehicle during a travel process; the output index includes a travel distance of the vehicle during the travel process.

Furthermore, for the respective input items of the vehicle, the pollutant emission amount and the carbon dioxide emission amount of the vehicle are calculated by vehicle exhaust on-line monitoring equipment or by vehicle emission model (for example, MOVES model and IVE model). The vehicle emission model usually needs the vehicle type, travel time, travel distance and other parameters of the vehicle, which can be obtained from the vehicle travel monitoring data such as GPS data and license plate recognition data of the vehicle and the vehicle registration database. The output item is the travel distance, which can be obtained according to the vehicle travel monitoring data such as GPS data and license plate recognition data of the to-be-allocated vehicle.

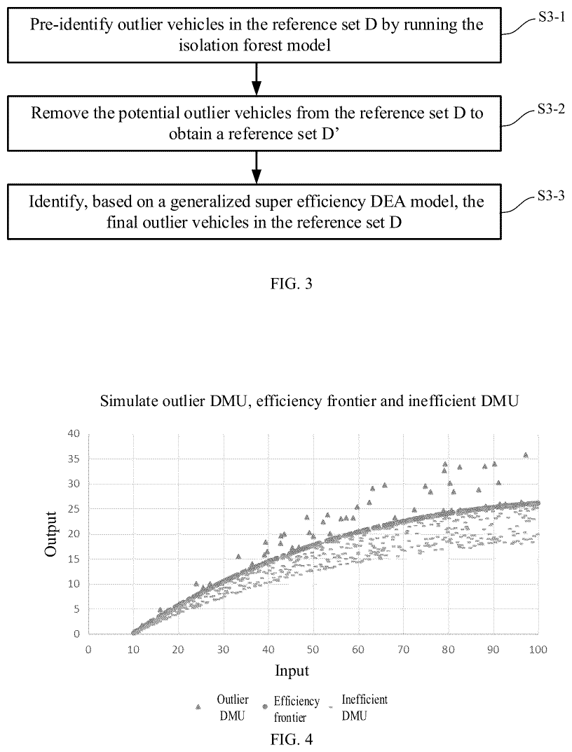

As shown in FIG. 3, the step S3 of identifying outlier vehicles by using a combination of isolation forest model-generalized super efficiency model includes steps S3-1 to S3-3.

At step S3-1, potential outlier vehicles in the reference set are pre-identified by running the isolation forest model. Each vehicle is equivalent to one point in a h*k-dimensional space, and the potential outlier vehicles in a multi-dimensional space are identified based on isolation forest algorithm. Parameters of the isolation forest model are set to default values (iTree number T=100 and sub-sampling size=256). For each vehicle, a corresponding anomaly score is obtained to represent an outlier degree of a vehicle, where those vehicles with the anomaly score greater than a given value are considered as outlier vehicles. The parameters of the isolation forest model can be set to default values (iTree number T=100 and sub-sampling size=256). The anomaly score representing the outlier degree of the vehicle is between 0 and 1, where the closer to 1 the anomaly score of the vehicle, the more possible is the anormal; and the closer to 0 the anomaly score, the more possible is the normal. When the anomaly score is approximately equal to 0.5, that is, when an average path length of the sample is approximate to an average path length of the iTree, it is very difficult to determine whether the vehicle is an outlier. As a result, 0.6 can be used as a reference threshold for identifying potential outlier vehicles, and those vehicles with the anomaly score greater than 0.6 can be determined as potential outlier vehicles.

At step S3-2, the potential outlier vehicles are removed from the reference set D. The labeled potential outlier vehicles are removed from the complete reference set D to obtain a reference set D′ with the potential outlier vehicles removed.

At step S3-3, based on a generalized super efficiency DEA model of the reference set D′, the final outlier vehicles in the reference set D are identified. The related super-efficiency model used to identify outlier vehicles obtains the super-efficiency score of to-be-evaluated vehicle only by eliminating the to-be-evaluated vehicles from all the vehicles as the reference set, and the reference set D′ can not be directly used to obtain the super-efficiency score of the to-be-evaluated vehicle. Therefore, the application is further improved to introduce the framework of the generalized super efficiency DEA model, with the vehicles in the reference set D as evaluation objects of the efficiency score, and with the vehicles in the reference set D′ as a reference set, the generalized super efficiency DEA model is run to evaluate the efficiency score of the vehicles in the reference set D. The directional distance function and the returns-to-scale setting are consistent with that in S1-4 and S1-5. With the radial distance function and the returns-to-scale being constant as an example, the programming formulations of the generalized super efficiency DEA model are as follows:

$$min φ , \qquad Formula 10$$

$$s . t . {\sum }_{r}^{-} {\overline{x}}_{r} {λ}_{r} \leq φ {\overline{x}}_{t} ,$$

$${\sum }_{r} {\overline{y}}_{r} {λ}_{r} \geq {\overline{y}}_{t} ,$$

$${λ}_{r} \geq 0 ,$$

$$r ∈ {D}^{′} ,$$

$$t ∈ D .$$

in the above model, φ represents a super efficiency score, λᵣ is a linear combination coefficient of an efficiency frontier vehicle, x̅ᵣ and y̅ᵣ represent an input index value and an output index value of vehicle r in the reference set D′, X̅ₜ and y̅ₜ represent an input index value and an output index value of vehicle/in the reference set D, where the input index includes a pollutant emission amount, a carbon dioxide emission amount, and a travel time of the vehicle, and the output index includes a travel distance of the vehicle;

when the returns-to-scale is variable, a constraint condition Σᵣλᵣ=1 is added to the formula (10), and other settings are unchanged;

those vehicles with the super efficiency greater than a given threshold are determined as final outlier vehicles, where the default value of the threshold is 1.

At step S4, the final outlier vehicles are removed from the reference set D to obtain a reference set D″ with the outlier vehicles being removed.

At step S5, for the to-be-allocated vehicle p to be allocated a quota, obtaining quota amounts θx₁ₚ, θx₂ₚ, . . . . θxₕₚ for the to-be-allocated vehicle p by running Formula 8 with the reference set D″ as the reference set, where θx₍ₕ₋₁₎ₚ represents quota amount of each pollutant (input) for the to-be-allocated vehicle p.

At step S6, in the management area, the quota allocation mechanism can update the reference set every certain time (for example, 12 hours, 24 hours) to adapt to the latest situation of regional vehicle driving and emission. Specifically, emission data and travel data of vehicles appearing in a period is added to the reference set D″ in step S5 to obtain the reference set D″, outlier vehicles in the reference set D′″ is identified continuously, and the identified outlier vehicles are removed to obtain a reference set D″″, which is an updated reference set.

### Embodiment 2

In combination with FIG. 1 to FIG. 4, the steps of the embodiment are described below. (I) Implementation steps are presented below.

At step S1-1, a quota allocation object is set: the quota allocation object is a DMU set on and within the efficiency frontier of the following dataset.

At step S1-2, an input index and an output index of the quota allocation model are set: it is assumed that the input index is one input x and the output index is one output y. The values of the x and y are obtained in the following manner. In this embodiment, it is assumed that one efficiency frontier having one input and one output is generated, where the frontier is formed by a cubic function y=x³−12x²+48x−37 of the domain of definition in the interval (1, 3]. For ease of observation, in this embodiment, the interval (1, 3] is transferred to (10, 100] in a unified way such that there are same corresponding outputs. If 1000 DMUs are randomly selected from the true efficiency frontier in this embodiment and these DMUs are just on the efficiency frontier, their efficiency scores (returns-to-scale being variable) are all equal to 1. Then, in this embodiment, 10% of points are randomly selected as outlier DMUs from the 1000 DMUs. In other words, in this embodiment, it is assumed that the probability that the DMUs are contaminated by noise (forming outlier DMUs) is 10%. For each outlier DMU, in this embodiment, an exponent of a half-normal distribution exp(|N(μ, σ²)|) is firstly used to generate a random noise score, where μ=0, and σ is randomly selected in (0,0.1]. Next, the output corresponding to the outlier DMUs is multiplied by the random noise score. Therefore, for the outlier DMUs, they are beyond the assumed efficiency frontier and the efficiency scores are greater than 1. For the remaining 90% of DMUs on the efficiency frontier, their random noise scores can be generated in the same way as the outlier DMUs and the corresponding outputs are multiplied by the random noise scores to generate inefficient DMUs. FIG. 4 is a schematic diagram of test data, where 100 of 1000 data points are efficient outlier DMUs and the remaining 900 are the DMUs on and within the efficiency frontier.

At step S1-3, a reference set for forming an efficiency frontier is set. The above 1000 DMUs are an initial reference set D with outlier DMUs un-removed.

At step S1-4, a distance function of the quota allocation model is set: a radial distance function is taken as an example.

At step S1-5, a returns-to-scale type is set: the returns-to-scale being variable is taken as an example.

At step S1-6, the quota allocation model is determined.

$$min θ , \qquad ( Formula 11 )$$

$$s . t . {\sum }_{m} {\overline{x}}_{m} {λ}_{m} \leq θ {x}_{p} ,$$

$${\sum }_{m} {\overline{y}}_{m} {λ}_{m} \geq {y}_{p} ,$$

$${λ}_{m} \geq 0 ,$$

$$m ∈ {D}^{″} ,$$

$${\sum }_{m} {λ}_{m} = 1.$$

In the above formula, the optimal solution θ represents an efficiency score of the DMU p, λₘ represents a linear combination coefficient of the DMU, and the quota amount is θxₚ.

At step S2, the unit output-input value for each input of the DMUs in the reference set is calculated, that is, the ratio of x to y is calculated.

At step S3-1, outlier DMUs in the reference set are pre-identified by running the isolation forest model. Each DMU has one feature value (x/y), and each DMU is equivalent to one point in a one-dimensional space. Based on the isolation forest algorithm, the outlier DMUs are identified. The parameters of the isolation forest model are set to default values (iTree number T=100 and sub-sampling size=256), and the DMUs with the anomaly score greater than 0.6 are considered as potential outlier DMUs. Herein, it is required to run the isolation forest algorithm ten times for the dataset, and take an intersection of 10 labeling results as potential outlier DMUs and label the potential outlier DMUs.

At step S3-2, the potential outlier DMUs are removed from the reference set D. The labeled potential outlier DMUs are removed from the complete reference set D to obtain a reference set D′ with the potential outlier DMUs removed. 153 of 1000 DMUs in the reference set D are identified as potential outlier DMUs. After the potential outlier DMUs are removed, the remaining 847 DMUs form a reference set D′ with the potential outlier DMUs removed.

At step S3-3, based on a generalized super efficiency DEA model of the reference set D′, the final outlier DMUs in the reference set D are identified. The above dataset is taken as an example. With 1000 DMUs in the reference set D as evaluation objects, and with 847 DMUs in the reference set D′ as a reference set, the generalized super efficiency DEA model is run to evaluate the efficiency scores of the 1000 DMUs in the reference set D (radial distance function and returns-to-scale being variable). In this way, the super efficiency scores of 1000 DMUs are obtained, where the super efficiency scores of 97 DMUs are greater than 1 and labeled as final outlier DMUs. The programming formulations of the generalized super efficiency DEA model are as follows:

$$min φ , \qquad ( Formula 12 )$$

$$s . t . {\sum }_{r = 1}^{847} {\overline{x}}_{r} {λ}_{r} \leq φ {\overline{x}}_{t} ,$$

$${\sum }_{r = 1}^{847} {\overline{y}}_{r} {λ}_{r} \geq {\overline{y}}_{t} ,$$

$${\sum }_{r = 1}^{847} {λ}_{r} = 1 ,$$

$${λ}_{r} \geq 0 ,$$

$$r ∈ {D}^{′} ,$$

$$t ∈ D .$$

At step S4, 97 final outlier DMUs are removed from 1000 DMUs in the reference set D to obtain a reference set D″ with the outlier DMUs being removed, where the reference set D″ includes 903 DMUs.

(II) Comparison of effects of different outlier DMU identification manners is presented below.

Comparison is performed on the effects of different outlier DMU identification methods.

\textcircled{1} True efficiency scores: the scores obtained by the DMUs on the efficiency frontier and the inefficient DMUs within the frontier after evaluation by the ordinary DEA model are taken as “true scores”.

\textcircled{2} Efficiency scores with the outlier DMUs un-removed: the scores are obtained by evaluating a total of 1000 DMUs by using the ordinary DEA model.

\textcircled{3} Efficiency scores after the outlier DMUs being removed by using the conventional super efficiency model: after 1000 DMUs are evaluated by using the conventional super efficiency DEA model, those DMUs with the efficiency score greater than 1 are considered as outlier DMUs and removed, and then the ordinary DEA model is run for the remaining DMUs to obtain the efficiency scores after the outlier DMUs being removed by using the conventional super efficiency model.

\textcircled{4} Efficiency scores after the outlier DMUs being removed by using the method of the present disclosure: the final outlier DMUs are identified from the total of 1000 DMUs by using the method of the present disclosure, and are removed, and then the ordinary DEA model is run for the remaining DMUs to obtain the efficiency scores after the outlier DMUs being removed by using the method of the present disclosure.

Herein, two indexes Mean Squared Error (MSE) and Mean Absolute Deviation (MAD) are introduced to represent a degree of approximation between the scores of \textcircled{2}, \textcircled{3} and \textcircled{4} and the true score \textcircled{1}. The MSE as shown in formula (14) is a measure to reflect a degree of difference between estimator and estimand. It is assumed that the true score of a DMU is δ, and the scores of \textcircled{2}, \textcircled{3} and \textcircled{4} are [symbol] [symbol] and [symbol] . With a DMU set having the scores \textcircled{2} and \textcircled{1} as an example, the MAD formula of the scores \textcircled{2} and \textcircled{1} of the set is as shown below:

$$MAD ( \tilde{δ} ) = \frac{1}{n} {\sum }_{i = 1}^{n} \vert \tilde{δ} - δ \vert \qquad ( Formula 13 )$$

The MSE can avoid the problem of mutual cancellation of errors, as shown in the formula (14) below.

$$MSE ( \tilde{δ} ) = {E ( \tilde{δ} - δ )}^{2} \qquad ( Formula 14 )$$

It can be seen from the above formulas that, the smaller MSE and the MAD represent the score obtained by this method is more approximate to the true score. In this embodiment, three scenarios of three different outlier DMU probabilities are set up, which are 5%, 10% and 15%, and 50 pieces of test data are generated by using the data generation method shown above for each scenario. For 50 pieces of test data for each of the scenarios with different outlier DMU probabilities, a mean value is calculated as shown in Table 1 below. As shown in the Table 1 below, in the scenarios of the outlier DMU probabilities, the method of the present disclosure is superior to the conventional super efficiency model method and reduces the error largely.

TABLE 1
Comparison of effects of different outlier DMU removal methods

| | Outlier DMU probability | | | | | |
|---|---|---|---|---|---|---|
| | 5% | | 10% | | 15% | |
| | Mean | Mean | Mean | Mean | Mean | Mean |
| | squared | absolute | squared | absolute | squared | absolute |
| \ | error | deviation | error | deviation | error | deviation |
| Outlier DMUs | 0.0115 | 0.1004 | 0.0166 | 0.1243 | 0.0139 | 0.1166 |
| un-removed | | | | | | |
| Removing outlier | 0.0042 | 0.0597 | 0.0079 | 0.0854 | 0.0081 | 0.0875 |
| DMUs by using | | | | | | |
| the conventional | | | | | | |
| super efficiency | | | | | | |
| DEA model | | | | | | |
| Removing outlier | 0.0020 | 0.0354 | 0.0039 | 0.0507 | 0.0038 | 0.0512 |
| DMUs by using | | | | | | |
| the present | | | | | | |
| disclosure | | | | | | |

### Embodiment 3

In this embodiment, data about travels and emissions of 190717 vehicles traveling between the 15th day and the 30th day, May 2018 from a traffic system of a city was taken as a case dataset. For the dataset, outlier vehicles have been labeled by using outlier DMU identification method of Khezrimotlagh et al. (see the document A nonparametric framework to detect outliers in estimating production frontiers. EUROPEAN JOURNAL OF OPERATIONAL RESEARCH, 2020. 286(1): p. 375-388.) to be compared with the effect of the present disclosure. The outlier DMU method developed by Khezrimotlagh et al. has the advantages of high accuracy, high degree of automation and less human interventions.

(I) Implementation steps are presented below.

At step S1-1, a quota allocation object is set: 51887 vehicles travelling on the 30, May 2018 (a time length of the to-be-allocated vehicles is 1 day), that is, 51887 to-be-allocated vehicles are formed.

At step S1-2, input index and output index of the quota allocation model are set: in this research, HC, CO, PM, NOₓ, CO₂ emissions and travel times of the vehicles are taken as input indexes and the travel distances of the vehicles are taken as output indexes.

At step S1-3, a reference set for forming an efficiency frontier is set: 138830 vehicles between the 15 and the 29, May 2018 are selected as the reference set.

At step S1-4, a distance function of the quota allocation model is set: a radial distance function is taken as an example.

At step S1-5, a returns-to-scale type is set: the returns-to-scale being constant is taken as an example.

At step S1-6, the quota allocation model is determined:

$$min θ , \qquad ( Formula 15 )$$

$$s . t . {\sum }_{m} {\overline{x}}_{m} {λ}_{m} \leq θ {x}_{p} ,$$

$${\sum }_{m} {\overline{y}}_{m} {λ}_{m} \geq {y}_{p} ,$$

$${λ}_{m} \geq 0 ,$$

$$m ∈ {D}^{″} .$$

In the above model, the optimal solution θ represents an efficiency score of the to-be-allocated vehicle p, and λₘ represents a linear combination coefficient of the vehicle, and the quota amount is θxₚ.

At step S2, a unit output-input value for each input of the vehicles in the reference set is calculated: HC emission of unit travel distance, CO emission of unit travel distance, PM emission of unit travel distance, NOₓ emission of unit travel distance, CO₂ emission of unit travel distance and travel time of unit travel distance are calculated. The emission amount is calculated by IVE model. The travel time and travel distance corresponding to the vehicle required for emission calculation are extracted from the vehicle license plate recognition data corresponding to the vehicle, and the vehicle type is obtained by matching the vehicle license plate number to the vehicle registration database.

At step S3-1, potential outlier vehicles in the reference set are pre-identified by running the isolation forest model: based on six feature values of each vehicle calculated in step S2, each vehicle is equivalent to one point in a six-dimensional space. The potential outlier vehicles are identified based on isolation forest algorithm. The parameters of the isolation forest model are set to default values (iTree number T=100 and sub-sampling size=256) to obtain an anomaly score of each vehicle. Those vehicles with the anomaly score greater than 0.6 are considered as potential outlier vehicles.

At step S3-2, the potential outlier vehicles are removed from the reference set D: those vehicles identified and labeled as potential outlier vehicles are removed from the complete reference set D to obtain a reference set D′ with the potential outlier vehicles removed. With the above dataset as an example, 8463 vehicles of 138830 vehicles in the reference set D are identified as potential outlier vehicles, and after the potential outlier vehicles are removed, the remaining 130367 vehicles form the reference set D′ with the potential outlier vehicles being removed.

At step S3-3, based on a generalized super efficiency DEA model of the reference set D′, final outlier vehicles in the reference set D are identified. Taking the above dataset as an example, with 138830 vehicles in the reference set D as efficiency score evaluation objects, and 130367 vehicles in the reference set D′ as the reference set, the generalized super efficiency DEA model is run to evaluate the efficiency scores of 138830 vehicles in the reference set D (radial distance function and returns-to-scale being constant). In this way, the super efficiency scores of 138830 vehicles can be obtained, where the super efficiency scores of 5472 vehicles are greater than 1 and these vehicles are labeled as final outlier vehicles. The programming formulations of the generalized super efficiency DEA model are as follows:

$$min φ , \qquad ( Formula 16 )$$

$$s . t . {\sum }_{r = 1}^{130367} {\overline{x}}_{r} {λ}_{r} \leq φ {\overline{x}}_{t} ,$$

$${\sum }_{r = 1}^{130367} {\overline{y}}_{r} {λ}_{r} \geq {\overline{y}}_{t} ,$$

$${λ}_{r} \geq 0 ,$$

$$r ∈ {D}^{′} ,$$

$$t ∈ D .$$

At step S4, 5472 final outlier vehicles are removed from 138830 vehicles of the reference set D to obtain a reference set D″ with the outlier vehicles being removed, where the reference set D″ includes 133358 vehicles.

(II) Comparison of effects of different outlier vehicle identification methods is presented below.

1. Identification effect of outlier vehicles.

In this embodiment, the same comparison method as the embodiment 2 is used for comparison.

\textcircled{1} True efficiency scores: the scores obtained by the non-outlier vehicles in the quota allocation reference set after evaluation by the ordinary DEA model are taken as “true scores”.

\textcircled{2} Efficiency scores with the outlier vehicles un-removed: the scores obtained by evaluating the entire 138830 vehicles in the quota allocation reference set by using the ordinary DEA model.

\textcircled{3} Efficiency scores after the outlier vehicles being removing by using the conventional super efficiency model: after 138830 vehicles in the quota allocation reference set are evaluated by using the conventional super efficiency DEA model, the vehicles with the efficiency score greater than 1 are considered as outlier vehicles and removed, and the ordinary DEA model is run for the remaining vehicles in the quota allocation reference set to obtain the efficiency scores after the outlier vehicles being removed by using the conventional super efficiency model.

\textcircled{4} Efficiency scores after the outlier vehicles being removed by using the method of the present disclosure: final outlier vehicles are identified from a total of 138830 vehicles in the quota allocation reference set by the method of the present disclosure, and are removed, and then the ordinary DEA model is run for the remaining vehicles in the quota allocation reference set to obtain the efficiency scores after the outlier vehicles being removed by using the method of the present disclosure.

As shown in the Table 2 below, in the scenarios of different outlier vehicle probabilities, the method of the present disclosure is superior to the conventional super efficiency model method and reduces the error largely.

TABLE 2
Comparison of effects of different outlier vehicle removal methods

| | Mean | Mean absolute |
|---|---|---|
| — | squared error | deviation |
| Outlier vehicles un-removed | 0.0060 | 0.0748 |
| Removing outlier vehicles | 0.0032 | 0.0552 |
| by using the conventional | | |
| super efficiency DEA model | | |
| Removing outlier vehicles | 0.0021 | 0.0404 |
| by using the model of the | | |
| present disclosure | | |

2. Running times of different outlier vehicle identification methods.

Sets of different vehicle numbers are randomly selected to test the outlier vehicle identification times of different methods. The running time of the present disclosure is 75% less than that of the outlier identification method of Khezrimotlagh, and about 50% higher than that of the super efficiency model. The following tests are all carried out in a computer with CPU Intel Core i5-7500, memory 8 GB and operating system win 10.

TABLE 3
Times (min) of different outlier vehicle identification methods

| | | | Present disclosure |
|---|---|---|---|
| | Super | | (isolation forest + |
| Vehicle | efficiency | Khezrimotlagh | generalized super |
| number | model | method | efficiency model) |
| 1099 | 2.1 | 12.2 | 3.0 |
| 4375 | 9.7 | 58.4 | 15.7 |
| 10343 | 19.8 | 122.1 | 30.2 |
| 17251 | 29.0 | 169.5 | 45.0 |

Difference of effects of the quota allocation after and before outlier vehicles are identified.

Quota allocation effect analysis is performed based on travel and emission data on the 30th day, May 2018 from a traffic system of a city, where the reference set includes the travel and emission data of the vehicles between the 15th day and the 29th day, May, and the outlier vehicles are identified and removed. The below are quota allocation effects of different outlier vehicle identification methods. The quota surplus/gap is calculated in the following formula:

$$Quota surplus / gap = vehicle quota amount - vehicle emission amount \qquad ( Formula 17 )$$

The emission amount of the vehicle is calculated by IVE model. The travel time and travel distance corresponding to the vehicle required for emission calculation are extracted from the vehicle license plate recognition data of the vehicle, and the vehicle type is obtained by matching the vehicle license plate number to the vehicle registration database.

The effects show that, compared with the conventional super efficiency method, the framework proposed in the disclosure can reduce the improper gap of the quota allocation, resulting in a reduction of 10% in total gap and a reduction of 6% in gap extreme values for the vehicles. Therefore, the disclosure can make the quota allocation more reasonable.

TABLE 4
Influence of different outlier vehicle identification
methods on the quota allocation results

| | | Ratio of total | Ratio of extreme |
|---|---|---|---|
| | | surplus/gap to | values (gap above |
| | | total vehicle | 50%) to total |
| Gas type | Scenario | emission | number for vehicles |
| HC(Hydrocarbon | No outlier | −74% | 48% |
| compound) as | vehicles | | |
| an example | identified | | |
| | Conventional | −70% | 45% |
| | super | | |
| | efficiency | | |
| | model | | |
| | The present | −64% | 42% |
| | disclosure | | |

For cities that have established a transportation emissions market, using outlier identification methods or traditional super-efficiency methods to calculate quotas can result in a large number of vehicles that are extremely short of quotas, which can cause excessive travel costs for these vehicles, affect the normal functioning of the city's transportation functions, and reduce the acceptance of the carbon market mechanism. Using the method disclosed in the application to calculate quotas allocated to the vehicles will reduce the number of vehicles that are extremely short of quotas, reduce the damage to urban transportation capacity while facing the pressure of emission reduction, and increase the operability of the carbon market mechanism.

Furthermore, in case of no conflicts, those skilled in the arts can perform combination on different embodiments or examples described in the specification and features in the different embodiments or examples.

It should be noted that the above embodiments of the present disclosure are used only to clearly describe the examples in the present disclosure rather than limit the implementations of the present disclosure. Persons of ordinary skill in the arts can also make various changes or variations based on the above descriptions. Herein, it is not necessary to and impossible to exhaust all embodiments. Any changes, equivalent substitutions and improvements and the like made within the spirit and principle of the present disclosure shall all fall within the scope of protection of the claims of the present disclosure.

1. An optimization method of outlier data identification in a traffic emission quota allocation process, comprising:
constructing a traffic emission quota allocation model;
calculating a unit output-input value for each input of each vehicle in a reference set D;
identifying outlier vehicles in the reference set D by using a combination of isolation forest model-generalized super efficiency model; and
removing final outlier vehicles from the reference set D to obtain a reference set D″ with the final outlier vehicles being removed;
calculating a quota amount of a to-be-allocated vehicle based on the reference set D″;
dynamically updating the reference set D″, and dynamically identifying the outlier vehicles.

2. The optimization method of claim 1, wherein constructing the traffic emission quota allocation model comprises:
setting a quota allocation object;
setting an input index and an output index of the quota allocation model;
setting the reference set D for forming an efficiency frontier, wherein the reference set D is selected from a set of travel processes of vehicles within a certain time and space range of quota management;
setting a distance function of the quota allocation model;
setting a returns-to-scale type, wherein the returns-to-scale type comprises returns-to-scale being constant and returns-to-scale being variable; and
determining the quota allocation model.

3. The optimization method of claim 2, wherein,
the quota allocation object represents a travel process of the to-be-allocated vehicle for a time length within the certain time and space range of the quota management.

4. The optimization method of claim 2, wherein,
the input index of the quota allocation model comprises a pollutant emission amount, a carbon dioxide emission amount and a travel time of the to-be-allocated vehicle during a travel process; wherein the pollutant emission amount and the carbon dioxide emission amount of the to-be-allocated vehicle are calculated by vehicle exhaust on-line monitoring equipment or calculated by vehicle emission model, and the travel time of the to-be-allocated vehicle is obtained from vehicle travel monitoring database.

5. The optimization method of claim 2, wherein,
the output index of the quota allocation model comprises a travel distance of the to-be-allocated vehicle; wherein the travel distance of the to-be-allocated vehicle is obtained from vehicle travel monitoring database.

6. The optimization method of claim 2, wherein the distance function is a radial distance function.

7. The optimization method of claim 2, wherein, when setting the returns-to-scale type, if a range with time as day or month scale is selected, the returns-to-scale is constant; when a range with time as year scale is selected, the returns-to-scale is variable.

8. The optimization method of claim 2, wherein when determining the quota allocation model,
in response to that the returns-to-scale is constant, there is the following model for a to-be-allocated vehicle p to be allocated a quota:
$$min θ , \qquad ( Formula 1 )$$
$$s . t . {\sum }_{m} {\overline{x}}_{m} {λ}_{m} \leq θ {x}_{p} ,$$
$${\sum }_{m} {\overline{y}}_{m} {λ}_{m} \geq {y}_{p} ,$$
$${λ}_{m} \geq 0 ,$$
$$m ∈ {D}^{″} .$$
in the above model, the optimal solution θ represents an efficiency score of the to-be-allocated vehicle p to be allocated a quota, λₘ represents a linear combination coefficient of an efficiency frontier vehicle, θxₚ represents a quota amount obtained by the to-be-allocated vehicle p, xₚ represents an input index value of the to-be-allocated vehicle p to be allocated a quota, and yₚ represents an output index value of the to-be-allocated vehicle p to be allocated a quota, X̅ₘ represents an input index value of the vehicle m in the reference set D, and y̅ₘ represents an output index value of the vehicle m in the reference set D; the input index comprises a pollutant emission amount, a carbon dioxide emission amount and a travel time of the vehicle; the output index comprises a travel distance of the vehicle;
in response to that the returns-to-scale is variable, a constraint condition Σₘλₘ=1 is added to the formula (1) and other settings are unchanged.

9. The optimization method of claim 4, wherein, calculating the unit output-input value for each input of each vehicle in the reference set D comprises:
for each input of each vehicle, calculating the unit output-input value for each input as follows:
$${E}_{h , k , m} = \frac{{Input}_{h , m}}{{Output}_{k , m}} \qquad ( Formula 2 )$$
wherein E_{h,k,m} represents a ratio of a value of h-th input to a value of k-th output of vehicle m, Input_{h,m} represents a value of the h-th input, and Output_{k,m} represents a value of the k-th output.

10. The optimization method of claim 2, wherein, identifying the final outlier vehicles by using a combination of isolation forest model-generalized super efficiency model comprises:
pre-identifying potential outlier vehicles in the reference set D by running the isolation forest model; wherein, each vehicle is equivalent to one point in a h*k-dimensional space, and identifying the potential outlier vehicles in a multi-dimensional space based on isolation forest algorithm;
setting parameters of the isolation forest model to default values, iTree number T=100 and sub-sampling size=256;
for each vehicle, obtaining a corresponding anomaly score, wherein the corresponding anomaly score represents an outlier degree of the vehicle, wherein those vehicles with the anomaly score greater than 0.6 are considered as the potential outlier vehicles;
removing the potential outlier vehicles from the reference set D to obtain a reference set D′;
identifying, based on a generalized super efficiency DEA model, the final outlier vehicles in the reference set D, and with the vehicles in the reference set D′ as a reference set of the generalized super efficiency DEA model, evaluating a super efficiency score of the vehicles in the reference set D;
wherein, in response to that the returns-to-scale is constant, programming formulations of the generalized super efficiency DEA model are as follows:
$$min φ , \qquad ( Formula 3 )$$
$$s . t . {\sum }_{r} {\overline{x}}_{r} {λ}_{r} \leq φ {\overline{x}}_{t} ,$$
$${\sum }_{r} {\overline{y}}_{r} {λ}_{r} \geq {\overline{y}}_{t} ,$$
$${λ}_{r} \geq 0 ,$$
$$r ∈ {D}^{′} ,$$
$$t ∈ D .$$
in the above model, φ represents a super efficiency score, λᵣ is a linear combination coefficient of a efficiency frontier vehicle, x̅ᵣ represents an input index value of vehicle r in the reference set D′ and y̅ᵣ represents an output index value of the vehicle r in the reference set D′, X̅ₜ represents an input index value of vehicle t in the reference set D and y̅ₜ represents an output index value of the vehicle t in the reference set D, wherein the input index comprises a pollutant emission amount, a carbon dioxide emission amount, and a travel time of the vehicle, and the output index comprises a travel distance of the vehicle;
in response to that the returns-to-scale is variable, a constraint condition Σᵣλᵣ=1 is added to the formula (3), and other settings are unchanged;
vehicles with the super efficiency score greater than 1 are determined as the final outlier vehicles; and
removing the final outlier vehicles from the reference set D′ to obtain the reference set D″ with the final outlier vehicles being removed.

11. The optimization method of claim 8, wherein calculating the quota of the to-be-allocated vehicle based on the reference set D″ comprises:
for the to-be-allocated vehicle p, running Formula 1 with D″ as the reference set, and obtaining θxₚ as the quota amount of respective pollutants of the to-be-allocated vehicle p.
